(19) United States
(12) Patent Application Publication
(10) Pub. No.: US 2013/0136851 A1
(43) Pub. Date: May 30, 2013

(54) METHOD OF FORMING ATO WITH HIGH THROUGHPUT AND ELLIPSOMETRY DIAGNOSTIC METHOD FOR THE TCO PROCESS

(71) Applicants: Guowen Ding, San Jose, CA (US); Mohd Fadzli Anwar Hassan, San Francisco, CA (US); Hien Minh Huu Le, San Jose, CA (US); Zhin-Wen Sun, San Jose, CA (US)

(72) Inventors: Guowen Ding, San Jose, CA (US); Mohd Fadzli Anwar Hassan, San Francisco, CA (US); Hien Minh Huu Le, San Jose, CA (US); Zhin-Wen Sun, San Jose, CA (US)

(73) Assignee: Intermolecular, Inc., San Jose, CA (US)

(21) Appl. No.: 13/307,341

(22) Filed: Nov. 30, 2011

(51) Int. Cl. C23C 14/54; C23C 14/34; C23C 14/08

(52) U.S. Cl. 427/8; 427/372.2

(57) ABSTRACT

A method for producing antimony doped tin oxide (ATO) films is discussed wherein the films are deposited by reactive sputtering using a non-poisoned mode and then annealed in an air ambient to fully oxidize the films and improve the resistivity and transmission characteristics, and the non-poisoned mode method could improve the throughput. A method using spectroscopic ellipsometry and an independent measurement of an additional optical or physical property is disclosed which results in a significantly improved prediction of the various optical and physical properties of the film, such that the method made the spectroscopic ellipsometry valuable for monitoring and controlling the process in real time, and valuable for determining the carrier density, mobility and their gradients within the film.

### FIELD OF THE INVENTION

The present invention relates generally to the formation of transparent conductive oxide (TCO) materials. Specifically, the present invention relates generally to the formation and control of antimony tin oxide (ATO) with high conductivity and high transmission. The present invention also relates generally to a diagnostic method for determining physical and optical properties of the deposited material.

### BACKGROUND OF THE INVENTION

Transparent conductive oxide (TCO) materials have applications in many areas. Examples include solar panels, flat panel displays, light emitting diodes (LED), electrochromic windows, etc. The TCO materials form conductors for supplying power and signals to devices formed on the substrate. Generally for the applications listed above, the substrates are transparent and the conductors must also be transparent so that they do not block the transmission of light through the assembly.

Many of the TCO materials used in the applications listed above are based on a doped tin oxide material. These materials have high transmission characteristics for light in the visible range (i.e. 0.38 μm<λ<0.78 μm). The most common dopant used is indium to form an indium tin oxide (ITO) material. However, indium is rare and increases the cost of the article using the ITO material.

Many deposition technologies have been used to deposit these TCO materials. Examples include reactive sputtering, evaporation, spray pyrolysis, chemical vapor deposition (CVD), sol-gel techniques, cathodic electrodeposition, printing, etc. Reactive sputtering is a promising deposition technique because it can be adapted to form high quality materials on large substrates.

The properties of the TCO materials are sensitive to the composition and the processing conditions during deposition and post-deposition treatments. Therefore, good control of the deposition parameters and the post-deposition conditions must be maintained to yield materials with the desired properties. As an example, the resistivity and transmission of TCO materials are sensitive to composition, post-deposition anneal temperature, and post-deposition anneal time.

Therefore, there is a need for methods that deposit TCO materials with the proper composition in a uniform manner and in a cost effective manner. Further, there is a need for methods that subject TCO materials to post-deposition treatments that lower the resistivity and increase the transmission characteristics. Further, there is a need for methods that can be used to monitor and control the properties of TCO materials.

Spectroscopic ellipsometry (SE) is a powerful technique for determining a wide variety of optical and physical properties of materials. The full spectra of the ellipsometric parameters Δ and Ψ as a function of wavelength from the ultraviolet region (UV) (wavelengths in the range of between about 10 nm and about 400 nm) to the infra-red region (IR) (wavelengths in the range of about 700 nm to about 300 μm) can be determined with a high degree of precision and accuracy in a few seconds. In practice, most commercial SE systems collect data between about 140 nm and about 2000 nm. Such data can also be processed to provide (i) the values of the dielectric functions (i.e. the real and the imaginary parts of the optical dielectric constant as a function of wavelength) of semiconductors, metals, and wide band gap materials; (ii) depth-profiles of interfaces, thin films, and multilayer structures with almost atomic resolution; (iii) the composition for any layers (bulk, interface, or surface) that are composites or alloys; (iv) the micro-roughness of the surface layer; and (v) the true near-surface temperature of samples in the process chamber when used as an in-situ diagnostic tool. Furthermore, the results discussed above obtained by SE are reliable and trustworthy, with excellent corroboration with independent results of cross-sectional transmission electron microscopy (XTEM), Rutherford backscattering spectrometry (RBS), and atomic force microscopy (AFM) studies on the same multilayer structures. In real-time spectroscopic ellipsometry (RTSE), which has just been developed and perfected, most of the above capabilities of SE can be achieved again through analysis of data collected in a matter of a few seconds, and hence RTSE is now ready for use in real-time monitoring and control during the growth of multilayer structures, thin films, etc. Thus the full potential and capabilities of this non-destructive, non-perturbing, and non-invasive technique are yet to be realized.

### SUMMARY OF THE DISCLOSURE

In some embodiments of the present invention, an antimony doped tin oxide material is formed using reactive sputtering wherein the process is operated in the “non-poisoned” mode. This leads to a higher deposition rate and a higher throughput yielding a lower cost manufacturing process. The material is then annealed to lower the resistivity and increase the transmittance of the material.

In some embodiments of the present invention, simultaneous measurements of the reflectivity and the optical properties as determined using spectroscopic ellipsometry are used to calculate the resistivity of the material. This technique may be used as a monitoring procedure to improve the control of the manufacturing process. The accuracy of the model was significantly improved so that the method could be used as an effective monitoring and control mechanism.

In some embodiments of the present invention, spectroscopic ellipsometry is used to investigate the TCO film carrier density, mobility and their gradients within the film, which is important for characterizing the TCO properties, trouble-shooting TCO processes, and investigating new TCO materials.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 presents data for resistivity as a function of Sb content in an ATO film according to some embodiments of the present invention.

FIG. 2 presents data for transmission as a function of wavelength in an ATO film as deposited and after an anneal treatment according to some embodiments of the present invention.

FIG. 3 presents data for transmission as a function of wavelength in an ATO film according to some embodiments of the present invention.

FIG. 4 presents data for the mean square error (MSE) from a uniqueness test for the prediction of the resistivity in an ATO film for 2 models according to some embodiments of the present invention.

FIG. 5 presents data for resistivity as a function of thickness in an ATO film according to some embodiments of the present invention.

FIG. 6 presents data for the mean square error (MSE) from a uniqueness test for the prediction of the scattering time in an ATO film for 2 models according to some embodiments of the present invention.

FIG. 7 presents data for the mean square error (MSE) from a uniqueness test for the prediction of the scattering time in an ATO film for 2 models according to some embodiments of the present invention.

FIG. 8A presents data for carrier concentration and resistivity as a function of Sb content in an ATO film according to some embodiments of the present invention.

FIG. 8B presents data for scattering time (tau) and mobility as a function of Sb content in an ATO film according to some embodiments of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In many of the TCO applications mentioned previously, ITO is the preferred material. However, indium has a number of drawbacks, namely toxicity and high cost. Replacing the indium dopant with antimony to form antimony-tin-oxide (ATO) has been investigated successfully. ATO is an attractive replacement for ITO due to its high conductivity, high light transmission characteristics, and chemical stability. However, these properties are sensitive to the composition and the processing conditions during deposition and post-deposition treatments. Therefore, methods that can be used to monitor and control the parameters used to deposit and treat ATO materials are required.

Reactive sputtering can be used to deposit ATO materials. In reactive co-sputtering, multiple metallic targets of Sb and Sn are used to deposit films using a sputtering atmosphere that is a mixture of Ar and O₂. Alternatively, a single target that is an alloy of the Sb and Sn can be used. Under some conditions, the O₂ is activated by the plasma process and forms a layer of metal oxide on the surface of the target which is then sputtered onto the substrate. When the surface of the target is primarily covered by a metal oxide film, then the process conditions are said to be in “poisoned” mode. That is, there is very little pure metal exposed on the surface of the target. Typically, the deposition rate in the poisoned mode is low due to the presence of the metal oxide. Generally, the poisoned mode produces ATO materials that are almost completely oxidized.

Alternatively, if the surface of the target is primarily covered with exposed metal, then the process conditions are said to be in “non-poisoned” mode. That is, there is very little metal oxide formed on the surface of the target. Typically, the deposition rate in the non-poisoned mode is higher due to the presence of the exposed metal. As used herein, “non-poisoned” mode reactive sputtering will be understood to be processes wherein the oxygen is less than 65% by volume of the sputtering atmosphere. Generally, the non-poisoned mode produces ATO materials that are deficient in oxygen. However, the oxygen deficiency may be addressed through post-deposition anneal treatments.

In some embodiments of the present invention, ATO films were deposited using a co-sputtering process from a Sb target and a Sn target in a sputtering atmosphere comprising a mixture of Ar and O₂. The diameter of each the targets was 50 mm. The power applied to the Sb target was 200 watts and yielded a power density of 10 watts/cm². The power applied to the Sn target was 100 watts and yielded a power density of 5 watts/cm². Power densities between about 1 and about 100 watts/cm² were found to be advantageous for these depositions. Lower power densities allowed better thickness control for thin films and higher power densities allowed better throughput for thicker films. One set of samples were deposited using an O₂ flow rate of 18 standard cubic centimeters (sccm) and an Ar flow rate of 8 sccm and yielded a film thickness of 283 nm. The oxygen comprised 70% by volume of the sputtering atmosphere. Under these conditions, the reactive sputtering process was operating in the poisoned mode as discussed previously. The as deposited resistivity for this set of samples was too high to measure at greater than about 10 Ωcm. A second set of samples were deposited using an O₂ flow rate of 12 sccm and an Ar flow rate of 8 sccm and yielded a film thickness of 955 nm. The oxygen comprised 60% by volume of the sputtering atmosphere. Under these conditions, the reactive sputtering process was operating in the non-poisoned mode as discussed previously. The as deposited resistivity for this set of samples was too high to measure at greater than about 10 Ωcm. The deposition rate for the ATO film deposited in the non-poisoned mode was three times higher than the deposition rate for the ATO film deposited in the poisoned mode.

Both sets of samples were then subjected to multiple post-deposition anneal treatments in air for about 20 minutes at each temperatures of about 180 C, about 310 C, about 460 C, and about 610 C. The resistivity was measured following each anneal treatment and is summarized in Table 1.

TABLE 1

| | 900 sec | Anneal | Anneal | Anneal | Anneal |
|---|---|---|---|---|---|
| | process | At 180 C. | At 310 C. | At 460 C. | At 610 C. |
| O₂ flow | Thickness | Resistivity | Resistivity | Resistivity | Resistivity |
| (sccm) | (nm) | (Ω cm) | (Ω cm) | (Ω cm) | (Ω cm) |
| 18 | 283 | 0.2711 | 0.1650 | 0.0083 | 0.0085 |
| 12 | 955 | >10 | >10 | 0.0022 | 0.0732 |

The resistivity of the set of samples that was deposited using the poisoned mode (i.e. 18 sccm O₂) generally improves as the anneal temperature is increased as shown in Table 1. The lowest resistivity value is obtained after the anneal treatment at 460 C. The resistivity increases as the annealing temperature is increased to 610 C indicating that the high temperature is degrading the film properties.

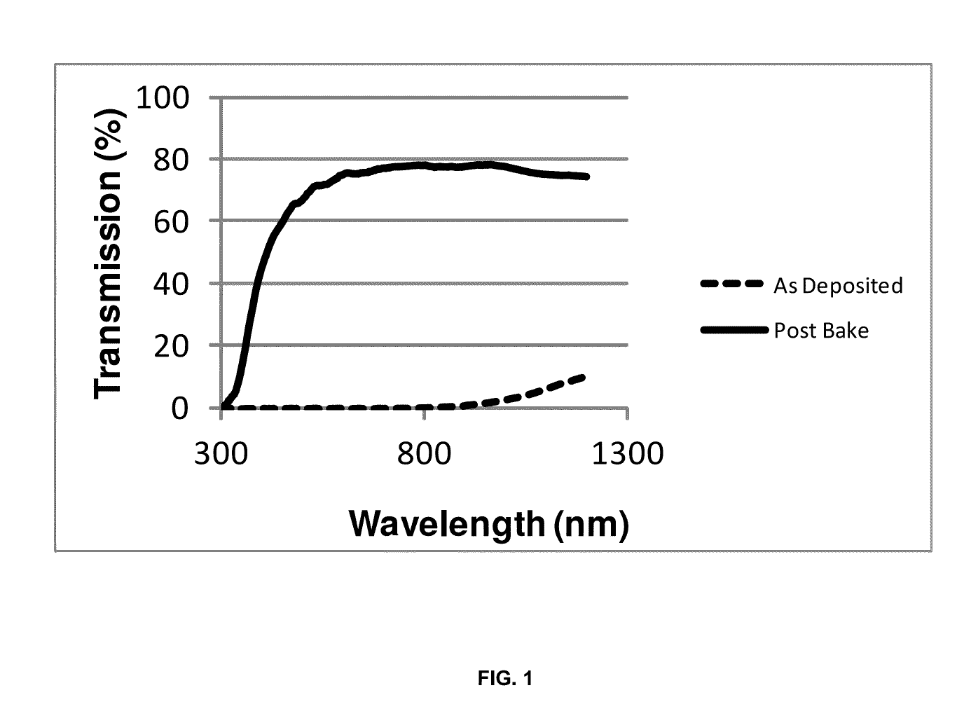

The resistivity of the set of samples that was deposited using the non-poisoned mode (i.e. 12 sccm O₂) generally improves as the anneal temperature is increased as shown in Table 1. The lowest resistivity value is obtained after the anneal treatment at 460 C. The resistivity increases as the annealing temperature is increased to 610 C indicating that the high temperature is degrading the film properties. At 460 C, the samples deposited using the non-poisoned mode exhibited a resistivity that was much lower than the samples deposited using the poisoned mode. Further, the samples deposited using the non-poisoned mode exhibited a dark color (i.e. low transmission characteristics) after deposition but became clear after the anneal treatments. The transmission characteristics for the as deposited and after the anneal at 460 C for 20 minutes are illustrated in FIG. 1.

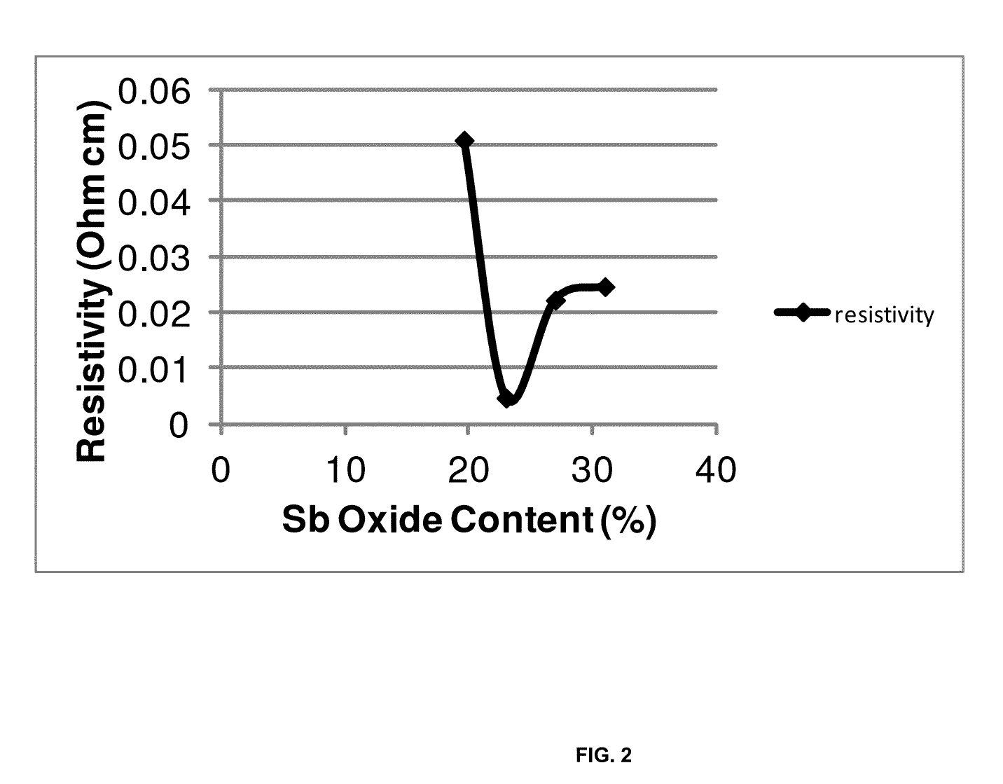

FIG. 2 illustrates the sensitivity of the resistivity of ATO films deposited in the non-poisoned mode after being annealed for 20 minutes at a temperature of 460 C. The composition (in volume %) of the SbO in the ATO film can be changed by varying the relative power provided to Sb target and the Sn target during the reactive sputtering process. The large change in resistivity over a small composition range requires that good control of the deposition parameters and the post-deposition treatment conditions be maintained. The concentration of SbO in the film is advantageously between about 20 volume % and about 25 volume %.

The narrow range of composition and narrow temperature window for the best ATO properties require close monitoring of the ATO transmission and resistivity. Methods have been developed to provide control of the ATO deposition process and post-deposition treatment conditions based on spectroscopic ellipsometry and models of the material's optical properties. Successful models should be able to derive material properties such as transmission, reflectivity, and resistivity. Conductivity in TCO materials are due to the free carriers formed by oxygen vacancies and their complex dielectric constant may be estimated using the Drude model as given by Equation 1 below.

$$\tilde{ɛ} ( λ ) = {ɛ}_{x} - \frac{i 4 π {ℏ}^{2}}{ρ ( ℏλ + i {λ}^{2} τ )} \qquad Eqn . 1$$

where ρ is the resistivity, and τ is the scattering time. Spectroscopic ellipsometry can be used to measure the polarization (i.e. p-polarized component and s-polarized component) of the reflected light to derive the ellipsometric parameters Δ and Ψ as a function of wavelength by measuring the change in polarization of the reflected beam as a function of wavelength. The ellipsometric parameters can then be determined from Equation 2 below.

ρ=tan(Ψ)e^{iΔ} Eqn 2

Note:—the “ρ” in Equation 2 is the ratio of the complex p-polarized component of the reflected beam over the complex s-polarized component of the reflected beam and is not the resistivity as noted in Equation 1.

Those skilled in the art will understand the general principles behind the analysis of spectroscopic ellipsometry data. However, a few of the salient points will be highlighted below. The complex dielectric function in Equation 1 can be derived by fitting the variation of Δ and Ψ as a function of wavelength using assumptions about the refractive index, n, and the extinction coefficient, k, of the material as well as other parameters such as surface roughness and film thickness. Generally, the models used to fit the data assume a multilayer structure. The fitting algorithms are complex, but have been well developed. Generally, these techniques can be used to determine physical properties such as film thickness, refractive index, surface roughness, interfacial mixing, composition, crystallinity, anisotropy, uniformity. Additional physical properties that may be determined comprise band-gap energy, resistivity, scattering time, carrier density, carrier mobility, and the gradient of these properties through the depth of the film.

Once the variation of Δ and Ψ as a function of wavelength has been satisfactorily modeled, the complex dielectric function is determined from Equations 3 and 4 below.

η~=n+ik Eqn 3

ε~=η~² Eqn 4

Equation 1 can then be used to calculate the resistivity, ρ, from Equation 1 above and then the carrier density (N) and carrier mobility (μ) can be determined from the resistivity as illustrated in Equation 5 below.

$$ρ = \frac{{m}^{*}}{{Nq}^{2} τ} = \frac{1}{q μ N} \qquad Eqn 5$$

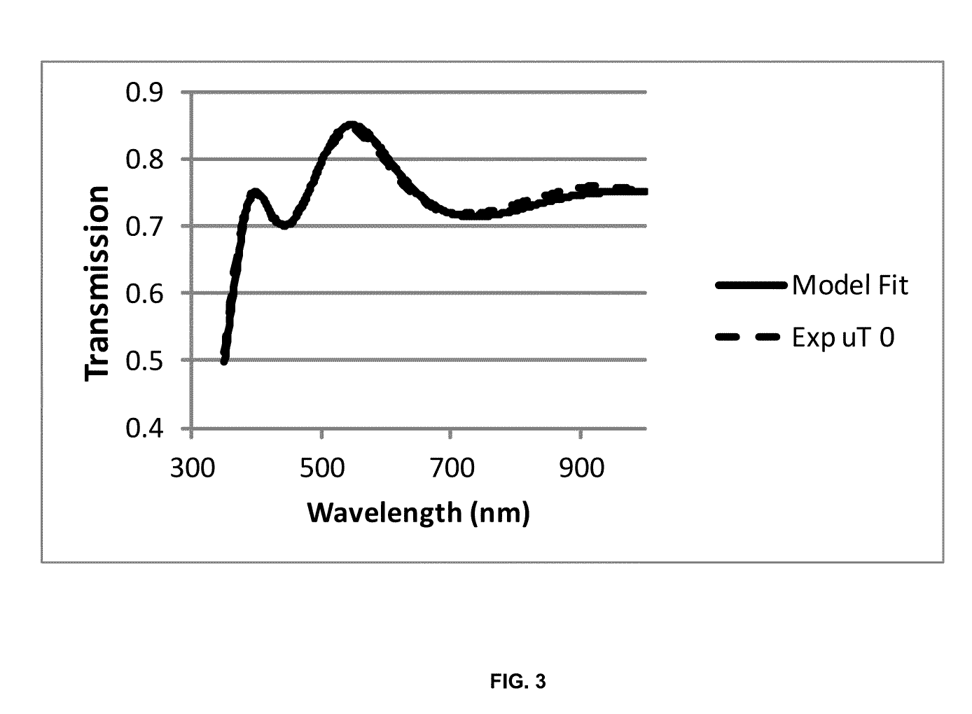

FIG. 3 illustrates a comparison between the measured transmission characteristics of an ATO film after the anneal treatment and the calculated model. The modeled transmission characteristics match the experimental data very well indicating that the optical and physical properties used in the model are accurate. The transmission could be easily determined from the model and can be used to derive the optical constants as discussed previously in Equation 2.

Generally, the spectroscopic ellipsometry measures only two variables, namely Δ and Ψ as a function of wavelength. As mentioned above, there are a wide variety of optical and physical properties that can be derived from these measurements. However, the problem is usually under-determined, meaning that there are more unknown quantities that there are measured quantities or equations. Therefore, assumptions must be made with respect to some of the parameters and the models must iterate until an acceptable error range is achieved. However, if a third, independent measurement of one of the other optical or physical properties can be made, then the model will converge with much greater accuracy. One method that can be used to quantify the accuracy of a model is to evaluate the uniqueness of the solution of the model, that is, to calculate the “mean square error (MSE)” of the model versus the experimental baseline. The MSE is simply the mean of the square of the errors at each point in the model.

To examine the sensitivity and uniqueness of a model to a specific parameter, it is useful to adjust the parameter in question to a fixed value while refitting all other parameters. If similar “fit” quality is achieved, the fit is insensitive to this particular parameter, at least within the range in which it was adjusted. One example of a measure of “fit” quality is the mean square error (MSE). A uniqueness test is a simulation of fit results for a model wherein one fit parameter is varied. The test parameter is fixed at a series of values while all remaining fit parameters are adjusted to find the best MSE.

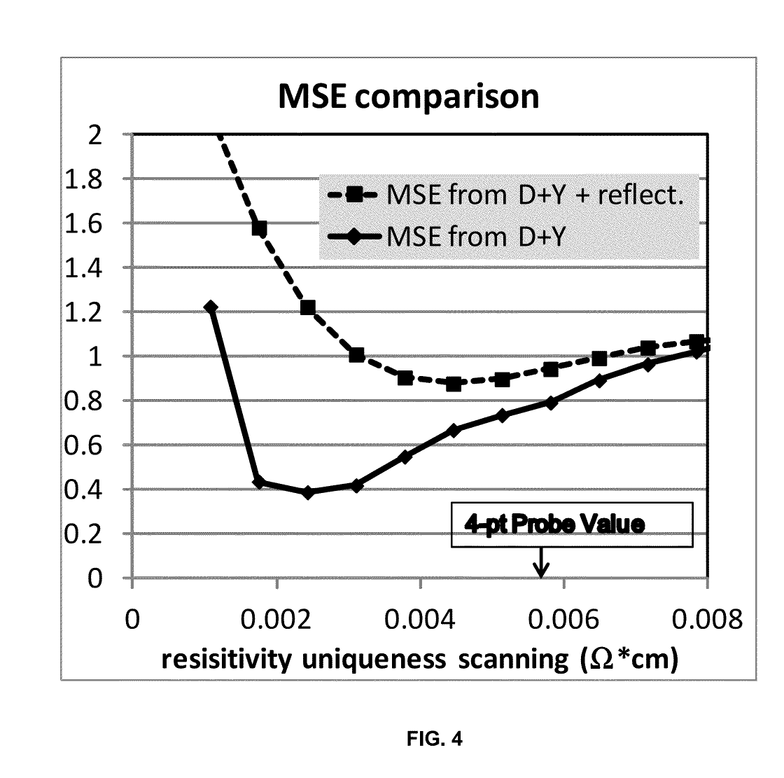

FIG. 4 presents data for the MSE from a uniqueness test for the prediction of the resistivity in an ATO film for 2 models according to some embodiments of the present invention. Spectroscopic ellipsometry data were used to generate a model of the optical and physical properties of an ATO film after an anneal treatment. The model was then used to calculate the expected resistivity of the sample. The expected resistivity will be at the minimum of the MSE versus resistivity plot. As can be seen in FIG. 4, the expected resistivity for the sample as predicted by the model using only the spectroscopic ellipsometry data was 0.0022 Ωcm. Additionally, the minimum in the MSE versus predicted resistivity curve is broad and flat. This indicates that any of the predicted resistivity values between about 0.015 Ωcm and about 0.003 Ωcm have the same MSE value. Therefore, the prediction of the resistivity being 0.0022 Ωcm cannot be made with a high degree of confidence. If these resistivity values were then used to calculate or predict other properties, then the prediction of those properties would also have low confidence levels.

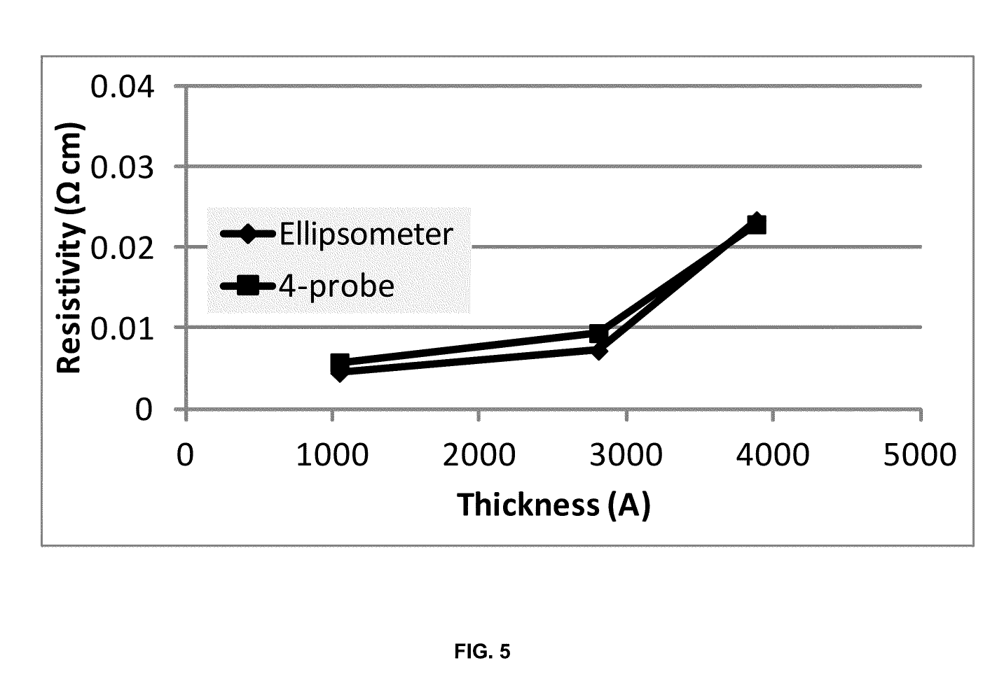

The near-normal reflectivity (within 8-degrees of normal) was independently measured and used to improve the accuracy of the model. As can be seen in FIG. 4, the expected resistivity for the sample as predicted by the model using the spectroscopic ellipsometry data with the additional near-normal reflectivity data was 0.0045 Ωcm. This agrees much better with the experimental value of 0.0058 Ωcm measured using a four-point probe. However, the curve is still somewhat broad. FIG. 5 illustrates a comparison of the enhanced model using both the spectroscopic ellipsometry data and the near-normal reflectivity with four-point probe collected over a range of film thicknesses. The agreement is quite acceptable. Therefore, a model based both spectroscopic ellipsometry data and near-normal reflectivity data may be used to accurately predict the resistivity of a TCO film and can be used as a process control method for ensuring that the composition of the TCO film is correct.

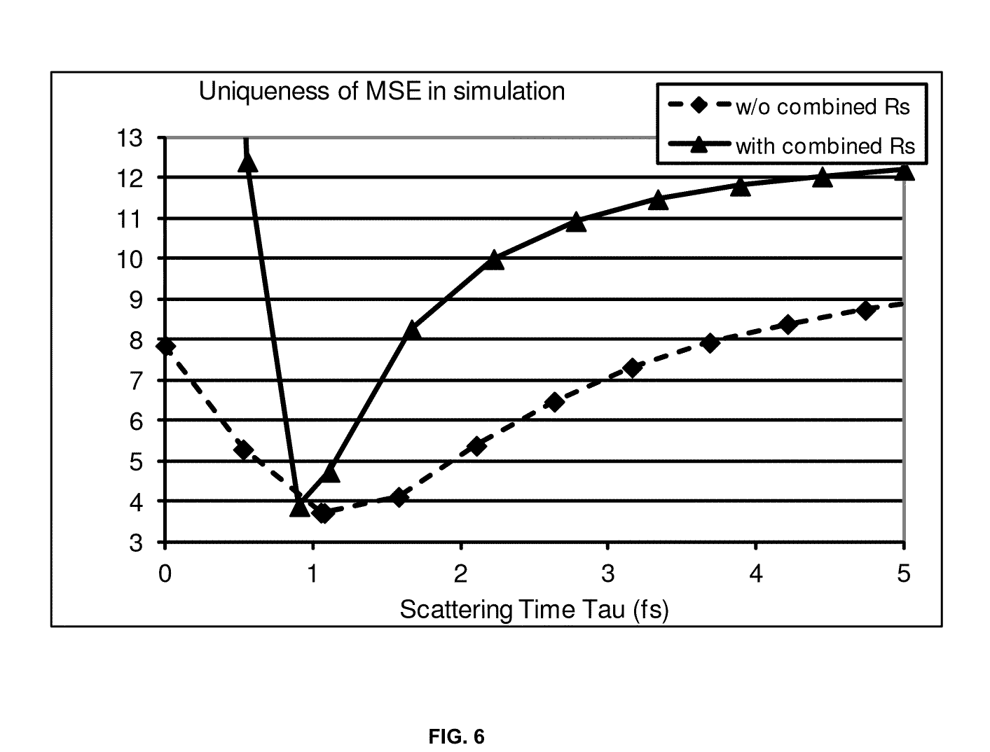

As mentioned previously, the conductivity in TCO materials is due to free carriers generated by oxygen vacancies in the material. To improve the performance of the materials, the carrier density and their mobility and how they change depending on deposition conditions and/or post-deposition treatment conditions need to be determined. As discussed previously, the carrier density and their mobility can be derived from spectroscopic ellipsometry data. However, like in the case of trying to derive the resistivity, the MSE fit can be improved if a third independent measurement can be made to enhance the model. FIG. 6 presents data for the mean square error (MSE) for the prediction of the scattering time in an ATO film for 2 models according to some embodiments of the present invention. In this case, the composition was uniform throughout the film thickness. As illustrated in Equation 5, the carrier density (Nₑ) and carrier mobility (μ) can be determined from the resistivity, but additional data is required because the problem is under-determined. Spectroscopic ellipsometry data were used to generate a model of the optical and physical properties of an ATO film after an anneal treatment. The model was then used to predict the expected scattering time (τ) of the sample. The expected scattering time will be at the minimum of the MSE versus scattering time plot. As can be seen in FIG. 6, the expected scattering time for the sample as predicted by the model using only the spectroscopic ellipsometry data was about 1 femto-second (fs), but was very broad indicating a lower confidence in the predicted values of the scattering time.

The resistivity was independently measured and used in the above ellipsometry method to improve the accuracy of the model. As can be seen in FIG. 6, the expected scattering time for the sample as predicted by the model using the spectroscopic ellipsometry data with the resistivity data was also about 1 fs, but the minimum is very sharp indicating a higher confidence in the predicted result. The scattering time predicted with high confidence can now be used to calculate the carrier density (Nₑ) and carrier mobility (μ), also with high confidence.

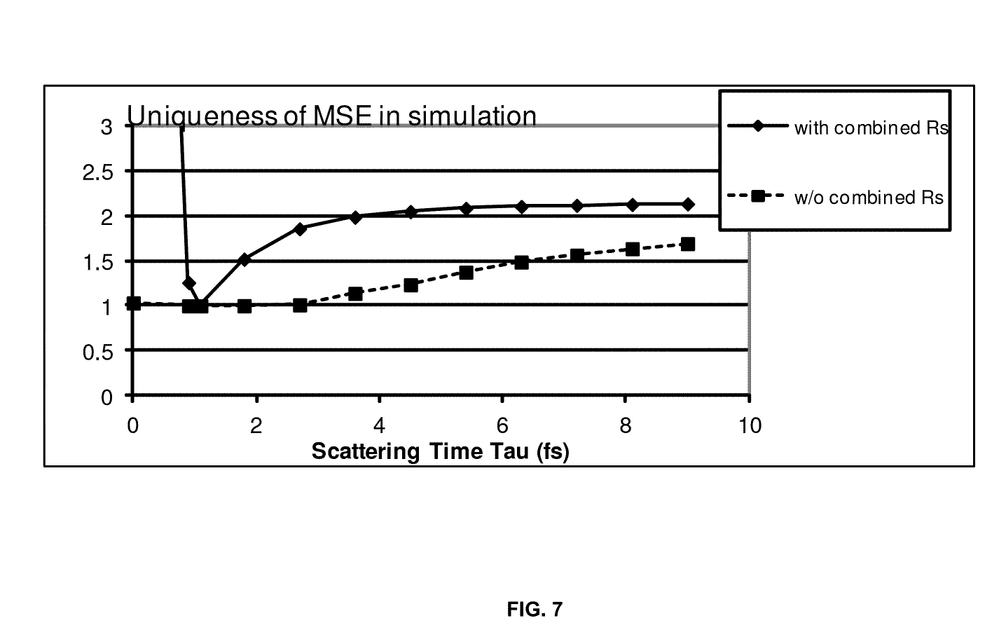

FIG. 7 presents data for the mean square error (MSE) for the prediction of the scattering time in an ATO film for 2 models according to some embodiments of the present invention. In this case, the composition was non-uniform throughout the film thickness. Therefore, physical properties such as the resistivity, carrier density, and mobility are expected to vary throughout the film. As illustrated in Equation 5, the carrier density (Nₑ) and carrier mobility (μ) can be determined from the resistivity, but additional data is required because the problem is under-determined. Spectroscopic ellipsometry data were used to generate a model of the optical and physical properties of an ATO film after an anneal treatment. The model was then used to calculate the expected scattering time (τ) of the sample. The expected scattering time will be at the minimum of the MSE versus scattering time plot. As can be seen in FIG. 7, the expected scattering time for the sample as predicted by the model using only the spectroscopic ellipsometry data was about 1 femto-second (fs), but was very broad. For example, the MSE is very similar for scattering times equal to 1 fs and for scattering times equal to about 0.001 fs. The use of this model would lead to a very large error in the predicted mobility. In fact, the MSE versus scattering time plot does not show a strong minimum and the confidence in predicting the scattering time would be very low. The resistivity was independently measured and used to improve the accuracy of the model. As can be seen in FIG. 7, the expected scattering time for the sample as predicted by the model using the spectroscopic ellipsometry data with the resistivity data was also about 1 fs, but the minimum is very sharp indicating a higher confidence in the predicted result.

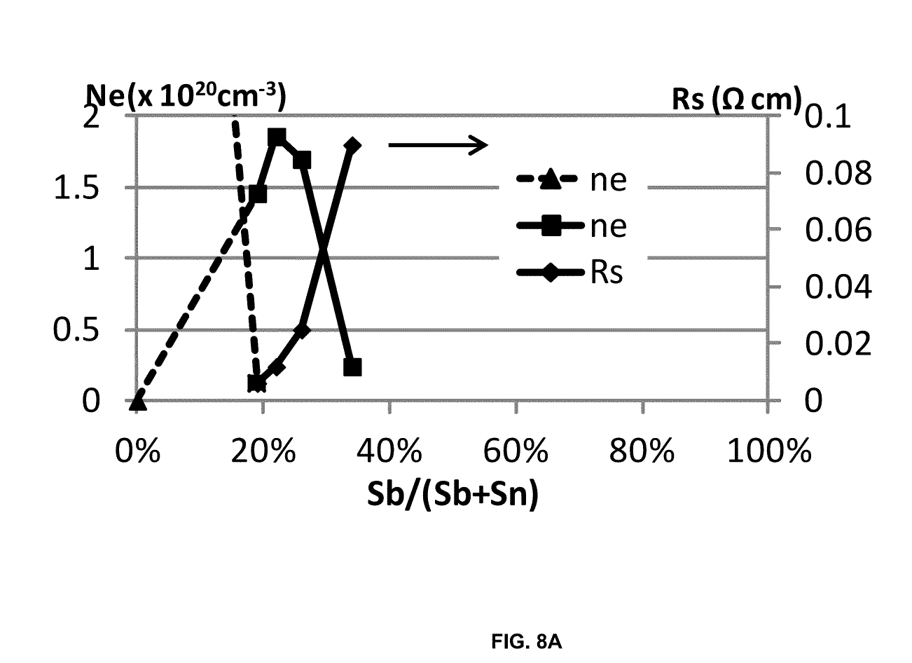

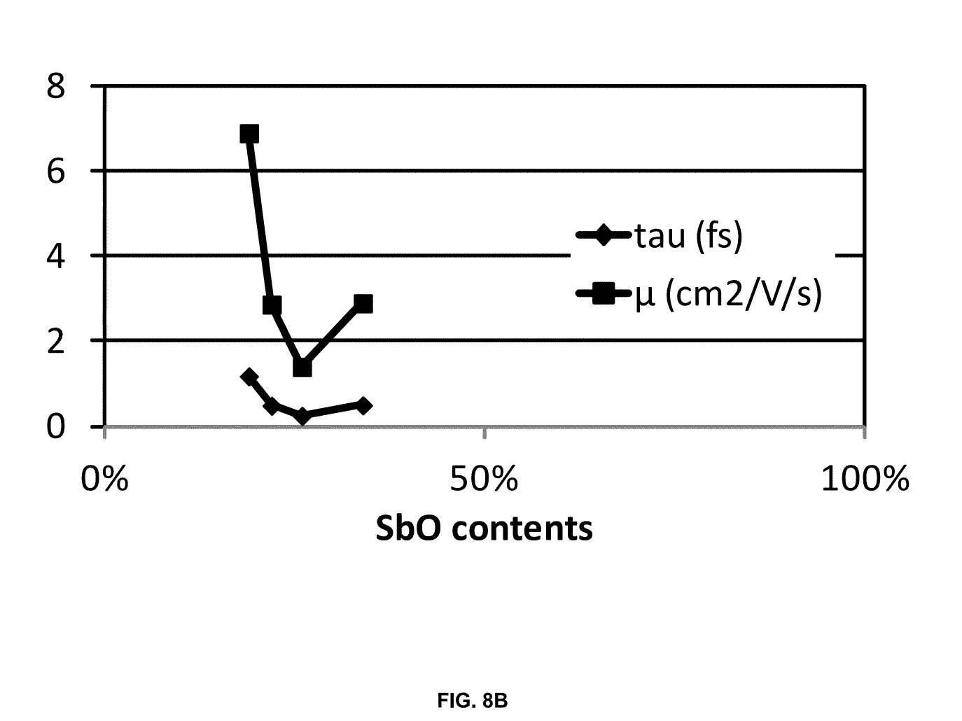

FIG. 8A presents data for carrier concentration and resistivity as a function of SbO content in an ATO film according to some embodiments of the present invention. ATO films with varying concentrations were prepared and their properties measured using SE. An additional property such as near normal reflectivity or resistivity was also measured and combined with the model based on the SE data. FIG. 8A presents the predicted values for the carrier density and the resistivity as a function of SbO content. Because of the methods described above, these values can be predicted with high confidence.

FIG. 8B presents data for scattering time (tau) and mobility as a function of Sb content in an ATO film according to some embodiments of the present invention. ATO films with varying concentrations were prepared and their properties measured using SE. An additional property such as near normal reflectivity or resistivity was also measured and combined with the model based on the SE data. FIG. 8B presents the predicted values for the scattering time and the mobility as a function of SbO content. Because of the methods described above, these values can be predicted with high confidence.

Gradients of the various optical and physical properties within TCO films are common, but the determination their magnitude is a challenge. Gradient simulation is widely used in connection with the spectroscopic ellipsometry method. The gradient simulation can be combined with the method described above and the gradient of properties such as carrier density and mobility could be uniquely determined. Although there are other techniques to determine the carrier density, (i.e. Hall probe) the spectroscopic ellipsometry methods according to embodiments discussed above provide a more accurate determination of the gradient of the carrier density and mobility.

ATO has been used throughout as an example. However, the improved method to use SE data to monitor and control the deposition of TCO films can be applied to any common TCO film. Examples include, Al:ZnO (AZO), InSnO (ITO), InZnO, B:ZnO, Ga:ZnO, F:ZnO, F:SnO₂, etc.

The discussion above has focused on an improved method to use SE data to monitor and control the deposition of TCO films in an “off-line” manner. That is, the samples are measured after the deposition is complete. It is possible to incorporate the optical path of an SE instrument into the deposition chamber such that the ellipsometric parameters Δ and Ψ as a function of wavelength, as well as reflection can be measured in real time. This can be coupled with an independent measurement of the near-normal reflectivity to allow the improved model discussed above to be used as a real-time, in-situ, non-destructive monitor and control system during the growth of the film. By combining reflection with the ellipsometric parameters Δ and Ψ, the accuracy of the resistivity prediction could be significantly improved. The calculated resistivity can be used as a feedback mechanism for controlling the power density or the oxygen flow rate in the co-sputtering deposition process to control the film composition. As discussed previously, the ellipsometry method alone is not accurate enough, but the new method is able to be accurate enough to act as a real time to monitor of the resistivity, thickness, transmittance, carrier density, mobility, etc. during the deposition of the film This method allows much greater control and uniformity for the deposition of the TCO film. As illustrated with respect to FIG. 2, important physical properties such as resistivity are very sensitive to fluctuations in composition, etc. Therefore, the improved model discussed above will have great benefits.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a transparent conductive oxide film comprising:
depositing a film by co-sputtering a first metal from a first target onto a substrate and a second metal from a second target onto a substrate, wherein the co-sputtering atmosphere comprises a mixture of argon and oxygen and wherein the oxygen is less than 65% by volume, and wherein the co-sputtering is operated at a power density for each target between about 1 and about100 watts/cm²; and
annealing the substrate after the depositing, wherein the annealing is performed at a temperature between about 310 C and 460 C.

2. The method of claim 1 wherein the annealing occurs in ambient air.

3. The method of claim 1 wherein the annealing occurs for about 20 minutes.

4. The method of claim 1 wherein the first target is tin.

5. The method of claim 1 wherein the second target is antimony.

6. The method of claim 5 wherein the concentration of antimony oxide in the film is between about 20 volume % and about 25 volume %.

7. The method of claim 1 wherein the first target is tin, wherein the second target is antimony, wherein the concentration of antimony oxide in the film is between about 20 volume% and about 25 volume %, and wherein the substrate is annealed at about 460 C for about 20 minutes.

8. A method for controlling a reactive co-sputtering deposition of a transparent conductive oxide, comprising:
measuring spectroscopic ellipsometric parameters Δ and Ω of the film as a function of wavelength during the deposition;
measuring a near-normal reflectivity of the film at an angle within 10 degrees of an angle normal to a surface of the film;
combining the spectroscopic ellipsometric parameters of the film as a function of wavelength and the near-normal reflectivity of the film to generate a model of the film used to calculate a resistivity of the film; and
adjusting one or more reactive co-sputtering deposition parameters of power density or oxygen flow rate based on the calculated resistivity.

9. The method of claim 8 wherein a physical property of the film is measured after the deposition, wherein the results of the physical property measurement are included in the model to calculate additional properties of the film.

10. The method of claim 9 wherein the physical property is a resistivity.

11. The method of claim 10, the calculated property is at least one of carrier density or mobility.

12. The method of claim 11, the gradient of the calculated property can be determined.

13. The method of claim 8 wherein the wavelength range is between about 140 nm and about 2000 nm.

14. The method of claim 8 wherein the measuring and combining are implemented as a real time control monitor during the deposition of the film.
